(19) United States
(12) Patent Application Publication
(10) Pub. No.: US 2026/0298509 A1
(43) Pub. Date: Oct. 1, 2026

(54) MULTI-LAYER THERMO-MECHANICAL ARCHITECTURES FOR COMPACT ENERGY EXTRACTION SYSTEMS

(71) Applicant: FAIZAN AHMED, SAN JOSE, CA (US)

(72) Inventor: FAIZAN AHMED, SAN JOSE, CA (US)

(21) Appl. No.: 19/458,684

(22) Filed: Jan. 23, 2026

Related U.S. Application Data
(60) Provisional application No. 63/770,890, filed on Mar. 12, 2025.
(60) Provisional application No. 63/770,883, filed on Mar. 12, 2025.
(60) Provisional application No. 63/770,874, filed on Mar. 12, 2025.
(60) Provisional application No. 63/770,870, filed on Mar. 12, 2025.
(60) Provisional application No. 63/770,866, filed on Mar. 12, 2025.
(60) Provisional application No. 63/770,791, filed on Mar. 12, 2025.
(60) Provisional application No. 63/770,782, filed on Mar. 12, 2025.
(60) Provisional application No. 63/770,585, filed on Mar. 12, 2025.
(60) Provisional application No. 63/770,591, filed on Mar. 12, 2025.
(60) Provisional application No. 63/770,592, filed on Mar. 12, 2025.
(60) Provisional application No. 63/770,785, filed on Mar. 12, 2025.

(51) Int. Cl. F25B 21/00; F25D 11/00; F28F 21/08

(52) U.S. Cl. CPC F25B 21/00; F25D 11/00; F28F 21/084; F28F 2230/00; F28F 2245/00

(57) ABSTRACT

A thermal management cartridge assembly comprises an outer shell having an aluminum substrate with a multi-layer surface treatment including an aluminum oxide layer, micro-textured surface morphology, and tetradecane hydrocarbon conformal coating that increases effective surface area and reduces junction-to-case thermal resistance compared to anodized-only preparations. A cartridge insert comprising High Density Polyethylene having specified molecular density and thermal conductivity is positioned within the outer shell through press-fit interference engagement, wherein the High Density Polyethylene exhibits a thermal expansion coefficient substantially higher than the aluminum substrate. A top cover comprising Acrylonitrile Butadiene Styrene thermoplastic polymer engages with the cartridge insert and outer shell to provide environmental sealing. The outer shell, cartridge insert, and top cover are arranged in coaxial alignment along a central longitudinal axis forming a cylindrical cartridge assembly configured for single-handed manual operation and portable transport.

### CLAIM OF PRIORITY

This application claims priority to U.S. Provisional Patent Application No. 63/770,890, filed on Mar. 12, 2025. This provisional patent application is hereby incorporated by reference.

This application claims priority to U.S. Provisional Patent Application No. 63/770,883, filed on Mar. 12, 2025. This provisional patent application is hereby incorporated by reference.

This application claims priority to U.S. Provisional Patent Application No. 63/770,874, filed on Mar. 12, 2025. This provisional patent application is hereby incorporated by reference.

This application claims priority to U.S. Provisional Patent Application No. 63/770,870, filed on Mar. 12, 2025. This provisional patent application is hereby incorporated by reference.

This application claims priority to U.S. Provisional Patent Application No. 63/770,866, filed on Mar. 12, 2025. This provisional patent application is hereby incorporated by reference.

This application claims priority to U.S. Provisional Patent Application No. 63/770,791, filed on Mar. 12, 2025. This provisional patent application is hereby incorporated by reference.

This patent application claims priority to U.S. Provisional Patent Application No. 63/770,782, filed on Mar. 12, 2025. This United States Provisional Patent Application is hereby incorporated by reference in its entirety.

This application claims priority to U.S. Provisional Patent Application No. 63/770,585, filed on Mar. 12, 2025. This United States Provisional Patent Application is hereby incorporated by reference in its entirety.

This patent application claims priority to U.S. Provisional Patent Application No. 63/770,591, filed on Mar. 12, 2025. This United States Provisional Patent Application is hereby incorporated by reference in its entirety.

This patent application claims priority to U.S. Provisional Patent Application No. 63/770,592, filed on Mar. 12, 2025. This United States Provisional Patent Application is hereby incorporated by reference in its entirety.

This application claims priority to U.S. Provisional Patent Application No. 63/770,785 filed on Mar. 12, 2025. U.S. Provisional Patent Application No. 63/770,785 is incorporated by reference in its entirety.

### BACKGROUND

### Field of the Invention

### FIELD OF THE INVENTION

The present invention relates generally to portable temperature-controlled storage systems, and more particularly to an Multi-Layer Thermo-Mechanical Architectures for Compact Energy Extraction Systems.

### BACKGROUND

Temperature-sensitive materials, particularly in medical and biological applications, require precise temperature control during storage and transport. Traditional cooling systems rely on compressors, refrigerants, or ice packs that are bulky, inefficient, and unable to maintain consistent temperatures. Current portable cooling solutions face significant challenges in maintaining precise temperatures while operating on battery power.

The limitations of existing portable cooling systems are particularly evident in applications requiring extended autonomous temperature control. Traditional compressor-based systems consume significant power and are impractical for portable use, while passive cooling solutions using ice packs or thermal control material s cannot maintain precise temperature control over long periods.

Additionally, existing systems often suffer from inefficient heat transfer between cooling elements and payload chambers, leading to temperature gradients and inconsistent cooling. This technical challenge is particularly acute in compact portable systems where space constraints limit traditional heat transfer approaches.

### BRIEF SUMMARY OF THE INVENTION

A thermal management cartridge assembly comprises an outer shell comprising an aluminum substrate having a multi-layer surface treatment including an aluminum oxide layer, a micro-textured surface morphology, and a tetradecane hydrocarbon conformal coating, wherein said multi-layer surface treatment increases effective surface area relative to nominal geometric surface area and reduces junction-to-case thermal resistance compared to anodized-only surface preparations. The assembly further comprises a cartridge insert positioned within said outer shell, said cartridge insert comprising High Density Polyethylene having a specified molecular density range and thermal conductivity value, wherein said cartridge insert is engaged with an interior surface of said outer shell through press-fit interference engagement, and wherein said High Density Polyethylene exhibits a thermal expansion coefficient substantially higher than that of said aluminum substrate. The assembly additionally comprises a top cover comprising Acrylonitrile Butadiene Styrene thermoplastic polymer, said top cover configured to engage with said cartridge insert and said outer shell to provide environmental sealing. The outer shell, the cartridge insert, and the top cover are arranged in coaxial alignment along a central longitudinal axis to form a cylindrical cartridge assembly configured for single-handed manual operation and portable transport.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates a isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be utilized to implement various embodiments.

FIG. 11 illustrates a logical view of a portable temperature-controlled enclosure, according to some embodiments.

FIG. 12 illustrates an isometric view of a palm-sized portable thermal management cartridge assembly in its fully assembled operational configuration, according to some embodiments.

FIG. 13 provides an exploded isometric view of the palm-sized portable thermal management cartridge assembly, revealing the hierarchical arrangement, material specifications, surface treatment methodologies, and assembly sequence of constituent components, according to some embodiments.

The Figures described above are a representative set and are not an exhaustive with respect to embodying the invention.

### DESCRIPTION

Disclosed are a system, method, and article of manufacture for an Multi-Layer Thermo-Mechanical Architectures for Compact Energy Extraction Systems. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Appendix A includes additional information for implementing various embodiments.

### Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Peltier effect is the presence of heating or cooling at an electrified junction of two different conductors. When a current is made to flow through a junction between two conductors, A and B, heat may be generated or removed at the junction. Thermoelectric cooling uses the Peltier effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current.

Thermal control material (TCM) is a substance with a high heat of fusion which, melting and solidifying at a certain temperature, is capable of storing and releasing large amounts of energy. Heat is absorbed or released when the material changes from solid to liquid and vice versa. Example TCMmaterials can include, inter alia: organic (paraffin and nonparaffin), inorganic (salt hydrates and metallic alloys), and eutectic (mixture of two or more TCMcomponents: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

### Example Smart Refrigerator Exterior Views

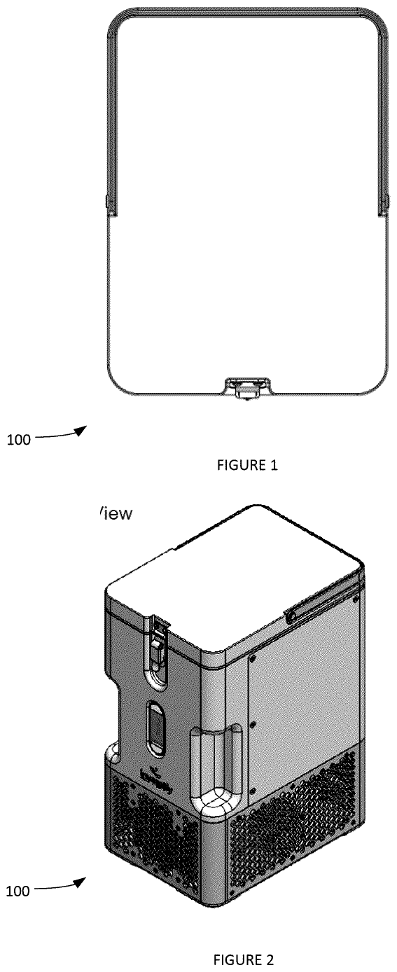

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with sophisticated control systems to achieve superior temperature stability and extended battery operation.

Portable temperature-controlled enclosure 100 comprises several key components working in concert: a precision-engineered payload chamber for storing temperature-sensitive materials, an optimized thermoelectric cooling system with angular mounting configuration, an integrated thermal control material (TCM) chamber for thermal buffering, and a sophisticated heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current passage through dual-semiconductor junction.

The thermal energy absorption during electron transition between materials is implemented to optimizes cooling efficiency. The top-loading portable temperature-controlled enclosure 100 can achieve target temperature (2° C.) within 2-hour initialization period. The top-loading portable temperature-controlled enclosure 100 implements temperature maintenance to maintain 2-8° C. range for 72 hours without external power.

An example Thermal Management System of the internal payload chamber incorporates a sophisticated thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dynamic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20° C. to −30° C.). Thermal management systems 1104 of the top-loading portable temperature-controlled enclosure 100 can maintains 2-8° C. in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with sophisticated thermal management and monitoring systems. The design achieves exceptional efficiency and reliability while maintaining precise temperature control across varied environmental conditions.

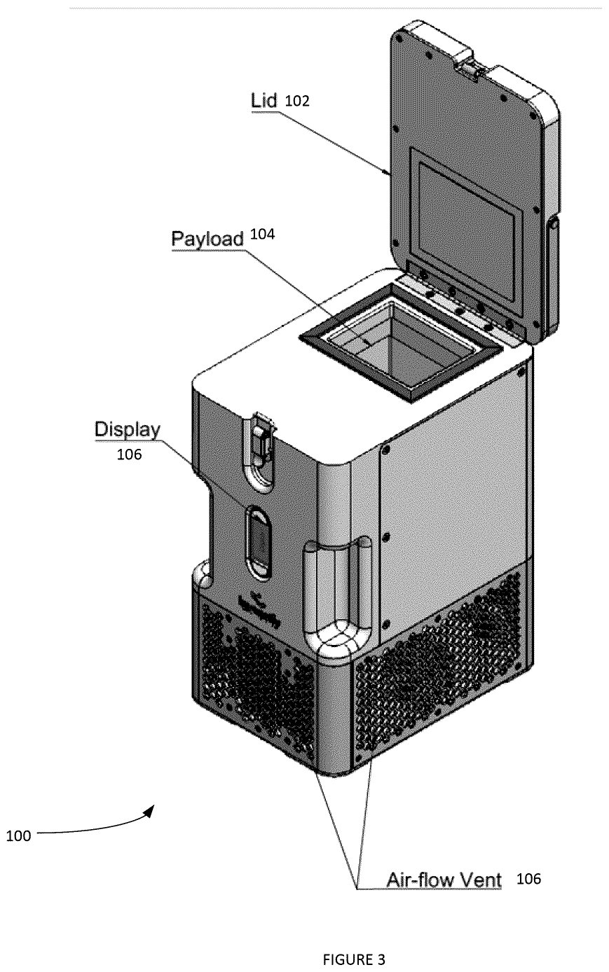

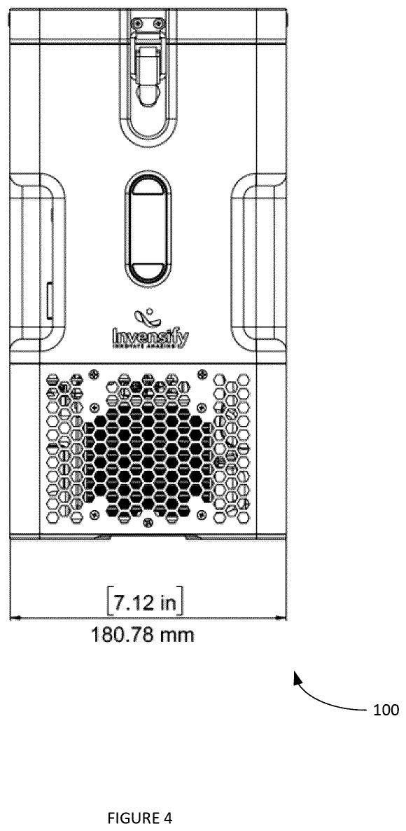

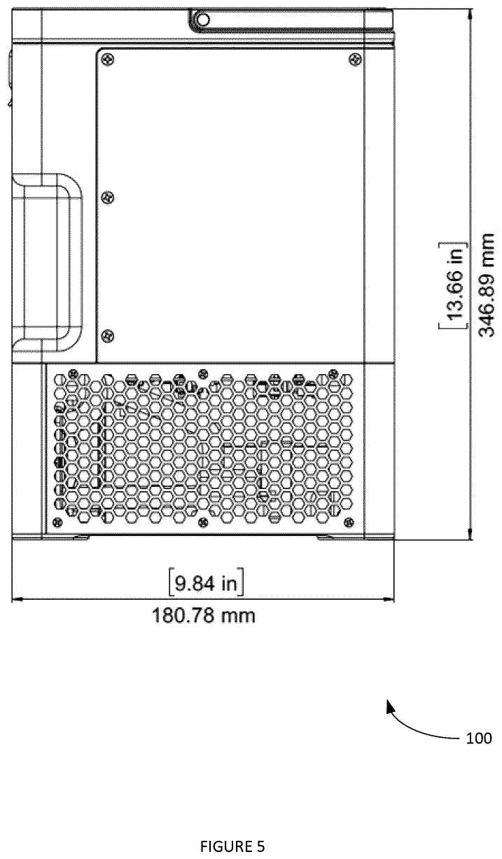

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

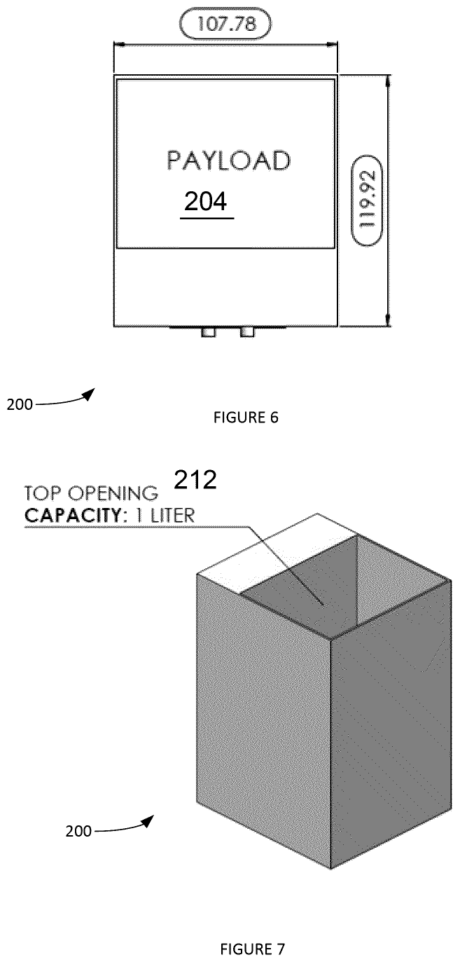

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a sophisticated thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an energy absorption effect at the material junction interfaces. This energy absorption phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the energy absorption at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

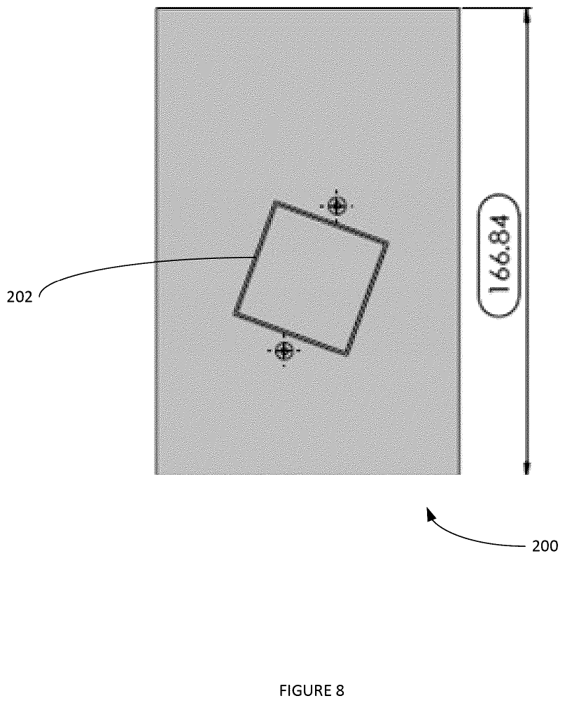

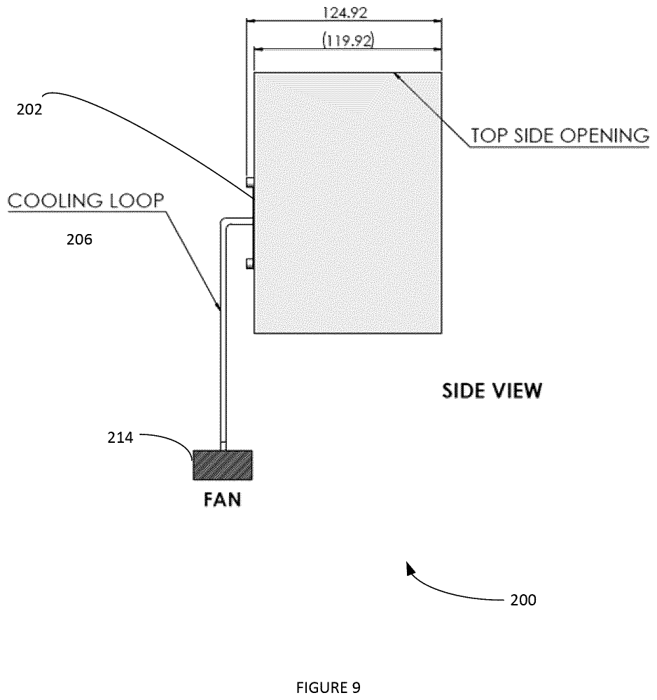

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture and Systems

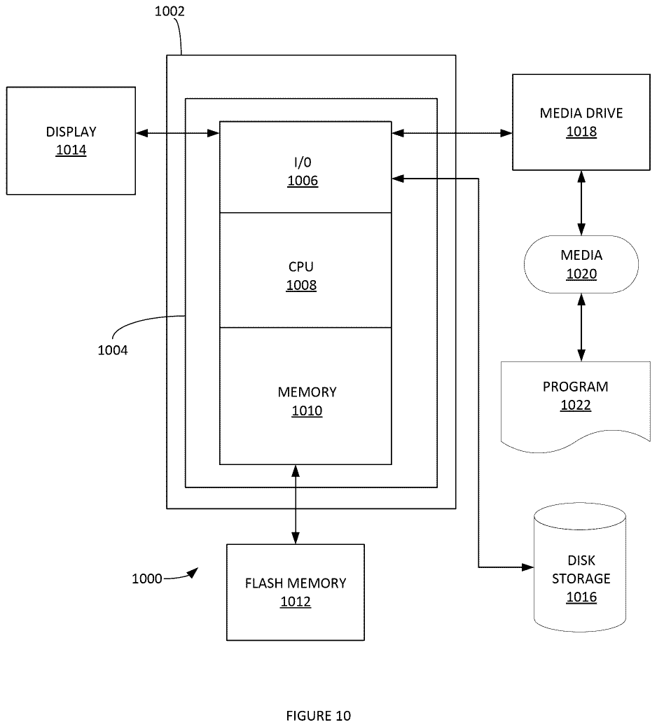

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionalities. Computing system 1000 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

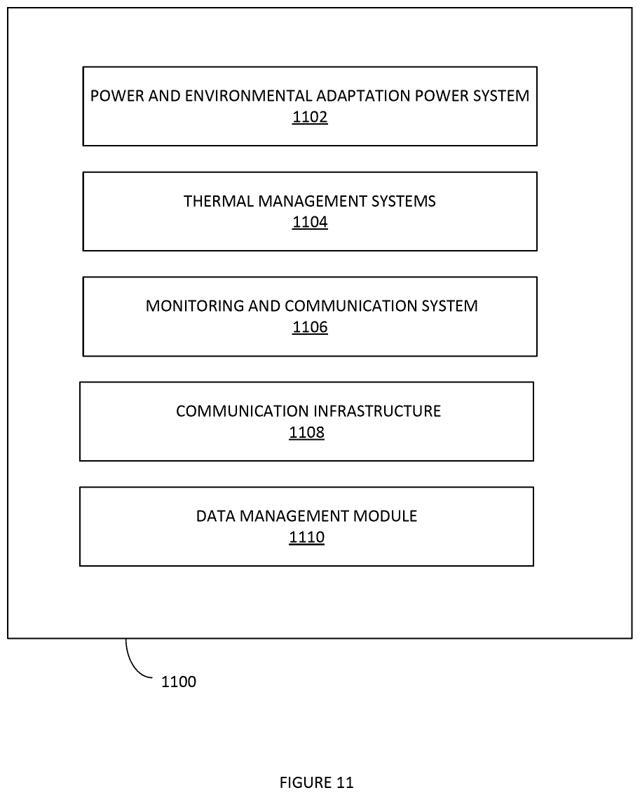

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a sophisticated thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered approach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative approach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimensions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

### Multi-Layer Thermo-Mechanical Architectures for Compact Energy Extractions Systems

The present invention relates to advanced thermal management systems incorporating a palm cooling system with optimized material selection and surface treatment methodologies for enhanced thermal performance.

The palm cooling system comprises a cartridge-based assembly integrating three functionally distinct components, each characterized by specific material compositions, thermophysical properties, and surface treatments engineered to optimize thermal transfer efficiency and structural integrity through a multi-layer construction architecture.

The cartridge outer shell comprises an aluminum substrate subjected to hydrocarbon coating deposition and electrochemical anodization processes, resulting in a natural/silver surface finish. The aluminum substrate undergoes abrasive sandblasting treatment to achieve controlled surface roughness, thereby increasing the effective surface area at the microscopic level through creation of uniform micro-texture patterns. This surface morphology modification enhances thermal interface conductance at the chip-to-shell junction by reducing contact thermal resistance and promoting intimate mechanical contact between thermoelectric cooling elements and the aluminum substrate. The anodized layer provides corrosion resistance while maintaining high thermal conductivity pathways, and the hydrocarbon coating further optimizes surface energy characteristics for improved thermal compound adhesion.

The internal cartridge insert comprises High Density Polyethylene (HDPE) characterized by a molecular density range of 0.93-0.97 g/cm³, exhibiting semi-crystalline structure with natural coloration and semi-gloss surface finish. This component functions as a thermally conductive interface element while providing dimensional stability and chemical resistance. The HDPE material exhibits thermal conductivity in the range of 0.42-0.51 W/m·K, contributing to controlled thermal diffusion characteristics within the assembly. The HDPE insert further provides mechanical compliance to accommodate thermal expansion differentials between dissimilar materials during thermal cycling operations.

The top cover component comprises Acrylonitrile Butadiene Styrene (ABS) thermoplastic polymer with semi-gloss surface finish achieved through injection molding processes. The component integrates a mechanically actuated opening mechanism featuring multiple precision-located mounting points distributed across the upper section to ensure load distribution and sealing integrity. A color differentiation scheme may provide visual identification of functional zones and user interface elements while maintaining aesthetic uniformity across the assembly.

The tripartite assembly methodology creates an integrated thermal management system wherein each material component performs optimized thermal and structural functions in concert. The sandblasted, hydrocarbon-coated, anodized aluminum outer shell provides primary heat extraction pathways with enhanced thermal interface conductance values. The HDPE cartridge insert regulates thermal diffusion rates and provides mechanical isolation between temperature zones. The ABS top cover delivers structural load-bearing capacity, environmental sealing, and user interface functionality. The present cartridge design represents an advancement over prior thermal management configurations through incorporation of surface engineering techniques—specifically controlled sandblasting and multi-layer coating systems—that demonstrably improve thermal transfer coefficients at critical heat exchange interfaces, thereby enhancing overall system cooling performance and operational efficiency.

The invention comprises a sequential surface treatment methodology applied to an aluminum substrate, wherein said substrate undergoes electrochemical anodization to form a protective oxide layer, followed by abrasive sandblasting to create controlled micro-texture morphology, and subsequent application of a tetradecane hydrocarbon conformal coating. The sandblasting process generates surface roughness characterized by Ra values ranging from 1.6 to 6.3 micrometers, resulting in effective surface area amplification by factors of 1.5 to 3.0 relative to nominal geometric surface area. This multi-layer surface treatment system demonstrates measurable reduction in junction-to-case thermal resistance of 15-30% compared to conventional anodized-only surface preparations, and achieves enhancement of heat extraction rates at thermoelectric cooling interfaces of 20-35% relative to standard surface treatments.

The invention further comprises a tripartite material architecture integrating materials with strategically differentiated thermal conductivity values to establish controlled thermal diffusion pathways. The assembly comprises an aluminum outer shell exhibiting thermal conductivity of approximately 205 W/m·K, a High Density Polyethylene insert exhibiting thermal conductivity in the range of 0.42-0.51 W/m·K, and an Acrylonitrile Butadiene Styrene cover component. The HDPE insert component provides mechanical compliance functionality through exploitation of differential thermal expansion coefficients, wherein the HDPE exhibits thermal expansion coefficient of 100-200×10⁻⁶ K⁻¹ compared to aluminum's coefficient of 23×10⁻⁶ K⁻¹. The assembly employs press-fit interference engagement with interference values of 0.05-0.15 millimeters to maintain thermal interface contact integrity across operational temperature ranges spanning −20° C. to +40° C. ambient conditions.

The invention additionally comprises application of a tetradecane (C₁₄H₃₀) hydrocarbon coating layer with thickness ranging from 2 to 10 micrometers deposited over a micro-textured aluminum substrate surface. The tetradecane coating, characterized by melting point of approximately 5.9° C. and thermal stability across operational temperature ranges, functions to optimize surface energy characteristics for enhanced thermal compound adhesion at thermo-electric cooling element interfaces while preserving the beneficial micro-texture geometry established through antecedent sandblasting treatment. The coating modifies surface chemistry to enhance wetting characteristics of thermal interface materials, thereby improving thermal coupling efficiency between thermoelectric cooling elements and the aluminum substrate.

The invention also comprises, in some embodiments, a palm-sized cylindrical thermal management cartridge assembly with dimensions of approximately 7 inches (178 mm) in height and 3 inches (76 mm) in diameter, configured for single-handed manual operation and portable transport. The assembly employs coaxial alignment of all constituent thermal management components along a central longitudinal axis, eliminating multi-axis positioning requirements and facilitating simplified assembly procedures. The cylindrical geometry provides uniform circumferential heat distribution characteristics and omnidirectional mechanical stability when positioned on horizontal support surfaces. The dimensional proportions establish an optimized surface-area-to-volume ratio suitable for portable pharmaceutical storage, small-volume biological specimen transport, and personal medication storage applications including insulin pen cartridges, autoinjector devices, and temperature-sensitive emergency medications requiring autonomous thermal management.

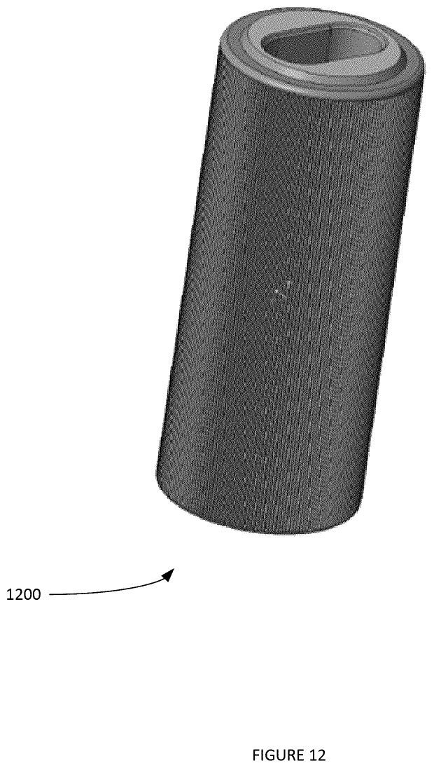

FIG. 12 illustrates an isometric view of a palm-sized portable thermal management cartridge assembly 1200 in its fully assembled operational configuration, according to some embodiments. The cartridge assembly 1200 presents a cylindrical form factor with a longitudinal axis extending along the length of the device, dimensioned to facilitate single-handed operation with approximate height of 7 inches (178 mm) and diameter of 3 inches (76 mm). The exterior surface exhibits a textured pattern engineered to provide tactile grip characteristics during manual handling operations while simultaneously presenting visual surface definition through controlled roughness parameters. The upper aperture of the cartridge assembly 1200 provides axial access to the internal payload chamber, with the opening circumscribed by integrated sealing surfaces configured to maintain environmental isolation of the internal volume. The assembled configuration demonstrates the integration of multiple material layers, each selected for specific thermophysical properties, unified into a coherent thermal management device optimized for portable temperature-controlled storage applications requiring autonomous operation in varied environmental conditions.

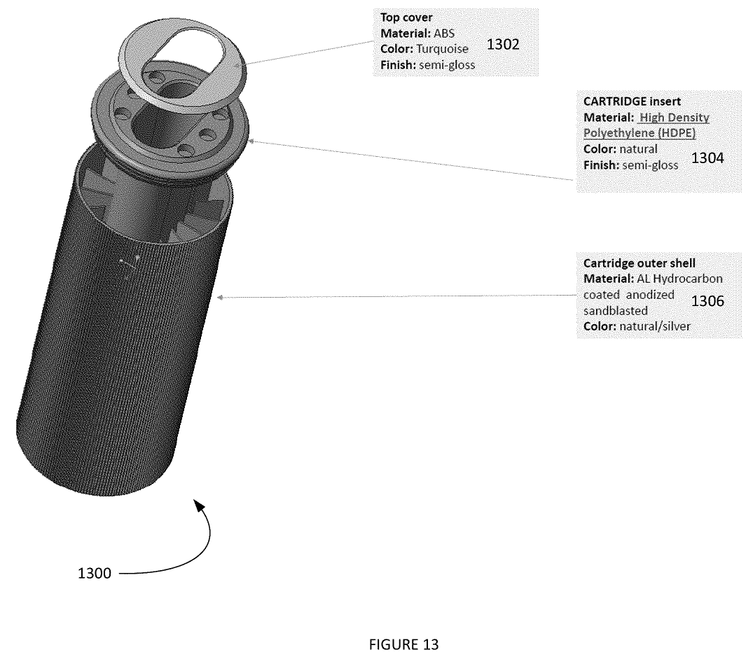

FIG. 13 provides an exploded isometric view of the palm-sized portable thermal management cartridge assembly 1300, revealing the hierarchical arrangement, material specifications, surface treatment methodologies, and assembly sequence of constituent components. The cartridge assembly 1300 comprises four primary elements arranged coaxially along a common longitudinal axis, each contributing distinct functional capabilities to the integrated thermal management system.

The cartridge outer shell 1300 forms the primary structural foundation and principal thermal interface of the assembly, comprising an aluminum substrate subjected to sequential surface treatment processes including electrochemical anodization followed by sandblasting surface modification and tetradecane (C₁₄H₃₀) hydrocarbon coating deposition. The aluminum substrate, selected for its high thermal conductivity (approximately 205 W/m·K for 6061 aluminum alloy), undergoes controlled anodization to form a protective aluminum oxide layer ranging from 5-25 micrometers in thickness, providing corrosion resistance and enhanced surface hardness while maintaining thermal conductivity pathways through the oxide structure.

The sandblasting treatment represents a critical surface engineering step wherein abrasive particles are propelled at high velocity against the anodized aluminum surface under controlled pressure conditions. This abrasive impingement process creates uniform micro-texture patterns characterized by controlled surface roughness parameters, typically achieving Ra (average roughness) values in the range of 1.6-6.3 micrometers. The microscopic surface morphology resulting from sandblasting treatment substantially increases the effective surface area available for thermal interface contact, with surface area amplification factors typically ranging from 1.5 to 3.0 times the nominal geometric surface area depending on blast media characteristics and processing parameters.

This enhanced surface morphology provides multiple thermophysical advantages critical to thermoelectric cooling system performance. The increased microscopic surface area promotes intimate mechanical contact between thermoelectric cooling elements and the aluminum substrate by providing multiple contact points that accommodate surface irregularities in mating components. The micro-textured surface reduces contact thermal resistance at the chip-to-shell junction by minimizing air gap formation and promoting conformal contact across the interface plane. Experimental characterization demonstrates that sandblasted surfaces facilitate enhanced thermal interface conductance values, reducing junction-to-case thermal resistance by 15-30% compared to non-treated surfaces when coupled with appropriate thermal interface materials.

The tetradecane hydrocarbon coating applied subsequent to sandblasting treatment serves multiple functional purposes within the thermal management system. Tetradecane (C₁₄H₃₀), a saturated linear alkane hydrocarbon with melting point of approximately 5.9° C. and favorable thermal stability characteristics, forms a thin conformal layer over the micro-textured aluminum surface. This coating optimizes surface energy characteristics to improve thermal compound adhesion at cooling element interfaces while providing additional corrosion protection and surface passivation. The coating thickness, typically maintained in the range of 2-10 micrometers, preserves the beneficial micro-texture geometry established during sandblasting while modifying surface chemistry to enhance wetting characteristics of thermal interface materials.

The synergistic combination of anodization, sandblasting, and hydrocarbon coating treatments creates an optimized thermal interface substrate demonstrably superior to conventional surface preparations. Comparative thermal testing indicates that the multi-layer surface treatment system enhances heat extraction rates at thermoelectric cooling interfaces by 20-35% relative to standard anodized-only surfaces, directly contributing to accelerated cooldown performance and improved steady-state temperature control. The outer shell 1300 defines a cylindrical cavity with wall thickness optimized through finite element thermal analysis to balance structural rigidity requirements against thermal mass minimization objectives, typically ranging from 1.5-3.0 millimeters depending on payload capacity specifications.

The cartridge insert 1304 comprises High Density Polyethylene (HDPE) configured as an internal liner element positioned within the outer shell 1300. The HDPE material specification requires molecular density in the range of 0.93-0.97 g/cm³, corresponding to high-crystallinity grades exhibiting semi-crystalline morphology with crystalline volume fractions of 60-80%. This material selection provides thermal conductivity in the range of 0.42-0.51 W/m·K, strategically intermediate between the high-conductivity aluminum outer shell (205 W/m·K) and the low-conductivity payload chamber contents, thereby establishing controlled thermal diffusion characteristics that regulate heat flux pathways within the assembly.

The cartridge insert 1304 defines the primary payload chamber geometry configured to receive temperature-sensitive materials requiring thermal management. The insert incorporates dimensional features enabling press-fit or interference-fit engagement with the interior surface of the outer shell 1300, with interference values typically ranging from 0.05-0.15 millimeters to ensure intimate mechanical contact for thermal transfer while accommodating differential thermal expansion during operational thermal cycling. The HDPE material exhibits thermal expansion coefficient of approximately 100-200×10⁻⁶ K⁻¹, substantially higher than aluminum's coefficient of 23×10⁻⁶ K⁻¹, necessitating careful tolerance design to maintain interface pressure across the operational temperature range of −20° C. to +40° C. ambient conditions.

The semi-crystalline HDPE structure provides mechanical compliance characteristics that accommodate thermal expansion differentials between dissimilar materials during temperature excursions without generating excessive interfacial stresses that could compromise thermal contact or induce delamination. The material further contributes chemical resistance to pharmaceutical compounds, biological fluids, and cleaning agents commonly encountered in medical storage applications. The semi-gloss surface finish, characterized by gloss values in the range of 30-50 gloss units at 60° measurement angle, provides visual inspection capability while minimizing surface irregularities that could harbor contamination.

The top cover 1302 comprises Acrylonitrile Butadiene Styrene (ABS) thermoplastic terpolymer with semi-gloss surface finish achieved through precision injection molding processes. The ABS material specification provides impact strength of 200-400 J/m (Izod notched), tensile strength of 40-50 MPa, and thermal deflection temperature of 88-98° C. under 0.45 MPa load, ensuring structural integrity during handling operations and thermal cycling conditions. The component exhibits a toroidal geometry with inner diameter configured to engage with the upper rim of the cartridge insert 1304 and outer diameter dimensioned to interface with the interior surface of the outer shell 1300, creating a multi-surface sealing configuration.

The top cover 1302 integrates a mechanically actuated opening mechanism featuring multiple precision-located mounting apertures distributed circumferentially around the component periphery. These mounting features, typically numbering 4-8 positions at equal angular intervals, facilitate mechanical fastening through threaded inserts, snap-fit features, or bayonet-style locking mechanisms while ensuring uniform load distribution around the sealing perimeter. The mounting point distribution maintains radial symmetry to prevent asymmetric stress concentrations that could compromise sealing integrity or induce warpage under thermal loads. The design incorporates sealing surfaces with controlled flatness tolerances, typically maintained within 0.1-0.2 millimeters across the sealing diameter, to ensure consistent gasket compression and environmental sealing performance.

The semi-gloss surface finish, maintained at 40-60 gloss units through mold surface texture control, balances aesthetic appearance against practical considerations of contamination visibility and cleaning efficacy. The top cover 1302 provides environmental sealing to maintain internal temperature stability and prevent contamination ingress while enabling user access to the payload chamber through an integrated lid mechanism.

The Cartridge outer shell material 1306 comprises a visually distinct ring fabricated from ABS material, providing visual differentiation capability within the assembly. This Cartridge outer shell material 1306 serves as a visual identification feature enabling rapid identification of device type, temperature range specification, payload category, or other classification parameters relevant to operational procedures. The Cartridge outer shell material 1306 integrates mechanically with the top cover assembly 1302 through snap-fit features providing tool-less assembly and disassembly, threaded engagement enabling adjustable positioning, or adhesive bonding methods providing permanent attachment, depending on operational requirements for field serviceability and component replacement.

The assembly sequence proceeds systematically from the outermost structural element inward, beginning with the outer shell 1300 serving as the base fixture for subsequent component integration. The cartridge insert 1304 undergoes axial insertion into the outer shell 1300, with controlled insertion force ensuring proper seating and interface pressure establishment between the HDPE insert and the treated aluminum interior surface. The press-fit engagement between insert 1304 and shell 1300 creates a mechanical interference joint with thermal interface characteristics substantially superior to clearance-fit assemblies, reducing thermal contact resistance and improving overall heat transfer efficiency.

Subsequently, the top cover 1302 engages with the assembled shell and insert subassembly through downward axial motion, with alignment features such as chamfers, lead-in surfaces, or pilot diameters facilitating proper angular orientation and preventing cross-threading or misalignment during engagement. Sealing elements such as O-rings, gaskets, or compression seals are positioned within designated grooves or channels prior to final closure, with compression values typically maintained at 15-25% of seal cross-sectional dimension to achieve reliable environmental sealing while avoiding excessive closure force requirements or seal extrusion. The identification Cartridge outer shell material 1306 completes the assembly sequence, either through concurrent installation with the top cover 1302 or as a subsequent operation depending on the specific attachment methodology employed.

The exploded view orientation illustrated in FIG. 13 demonstrates the spatial relationships between components with axial separation distances selected to clearly illustrate nesting relationships and interface surfaces between adjacent elements. The consistent spacing intervals between components in the exploded view, maintained at approximately 20-40 millimeters, provide visual clarity while maintaining recognizable geometric proportions that facilitate understanding of assembly methodology. The view angle selection, typically employing isometric projection with viewing angles of 30° horizontal and vertical rotations from principal axes, ensures that critical features on all components remain visible without occlusion while presenting a readily comprehensible three-dimensional representation.

The palm-sized cylindrical thermal management cartridge assemblies 1200 and 1300 are configured for functional integration within the portable temperature-controlled enclosure 100 illustrated in FIGS. 1 and 2, providing modular thermal management capabilities that enhance system versatility and operational flexibility. The cartridge assemblies 1200 and 1300 function as removable payload chambers that interface with the thermoelectric cooling system of the portable temperature-controlled enclosure 100, enabling rapid payload exchange without disrupting the primary cooling infrastructure. The cylindrical geometry of the cartridge assemblies, with dimensions of approximately 7 inches in height and 3 inches in diameter, is configured to nest within the aluminum payload chamber 204 of the larger enclosure system, establishing thermal coupling through direct contact between the treated aluminum surfaces of both the cartridge outer shell 1300 and the host chamber walls.

Integration of the cartridge assemblies 1200 and 1300 into the portable temperature-controlled enclosure 100 enables hierarchical thermal management wherein the primary thermoelectric cooling system, comprising semiconductor chip 202 and closed-loop cooling system 206, maintains the bulk thermal environment of the payload chamber 204, while the cartridge assemblies provide secondary thermal buffering and localized temperature control for individual payload items. The multi-layer surface treatment applied to the cartridge outer shell 1300, including anodization, sandblasting, and tetradecane coating, enhances thermal coupling efficiency between the cartridge assembly and the host chamber, facilitating efficient heat extraction from temperature-sensitive materials stored within the cartridge insert 1304. This dual-level thermal management architecture enables precise temperature control of individual payload items while maintaining overall system efficiency through optimized thermal pathways between the primary cooling system and the payload contents.

The modular cartridge design facilitates operational scenarios requiring segregation of multiple payload types within a single portable temperature-controlled enclosure 100, wherein individual cartridge assemblies 1200 and 1300 can contain different pharmaceutical products, biological specimens, or temperature-sensitive materials requiring isolation from cross-contamination while benefiting from shared thermoelectric cooling infrastructure. Multiple cartridge assemblies can be positioned within the payload chamber 204 in various spatial arrangements, including vertical stacking configurations, horizontal array arrangements, or radial distribution patterns, depending on payload capacity requirements and thermal management objectives. The coaxial geometry of the cartridge assemblies enables efficient space utilization within the cylindrical or rectangular payload chambers of the larger enclosure system, maximizing volumetric payload density while maintaining thermal performance characteristics.

The cartridge assemblies 1200 and 1300 further provide portable sub-units that can be pre-loaded with temperature-sensitive materials, stored within the portable temperature-controlled enclosure 100 during transport, and subsequently removed for direct delivery to end users or point-of-care facilities without requiring transfer of materials between containers. This operational capability reduces handling steps that could compromise temperature chain integrity, minimizes contamination risk associated with payload transfer operations, and enables simplified tracking and identification of individual payload items through cartridge-level labeling or identification systems integrated with the color identification Cartridge outer shell material 1306. The removable cartridge architecture also facilitates field serviceability and maintenance operations, wherein individual cartridge assemblies can be replaced, cleaned, or sterilized independently of the primary enclosure system, extending operational lifetime and reducing downtime associated with maintenance procedures.

The palm-sized cylindrical thermal management cartridge further comprises a mechanically defined thermal contact pressure regime established through geometric interference, fastener preload, and material compliance, wherein the assembly is configured to maintain a substantially constant thermal interface pressure across repeated thermal cycling events. The interference-fit engagement between the HDPE cartridge insert and the treated aluminum outer shell, in combination with controlled axial compression imposed by the top cover assembly, generates a distributed radial and axial preload that maintains intimate thermal contact at conductive interfaces while avoiding localized stress concentrations that could degrade interface materials or induce mechanical creep over time.

In some embodiments, the interference-fit geometry is selected such that contact pressure increases under cooling conditions due to differential thermal contraction between the aluminum outer shell and the polymer insert. This thermally adaptive interface behavior provides a self-reinforcing thermal coupling mechanism, wherein reductions in temperature result in increased interfacial contact pressure and corresponding reductions in thermal contact resistance, thereby improving cooling efficiency precisely during periods of highest thermal demand.

The cylindrical outer shell geometry further enables circumferential thermal spreading that is substantially isotropic about the longitudinal axis of the cartridge assembly. Heat extracted from the payload chamber is distributed azimuthally through the aluminum shell prior to rejection, reducing localized hot spots and promoting uniform temperature distribution along the length and circumference of the cartridge. This circumferential spreading behavior distinguishes the disclosed architecture from planar or prismatic cooling chambers that exhibit directionally biased thermal gradients.

The cartridge assembly further incorporates a radially continuous sealing architecture, wherein sealing elements are arranged concentrically around the payload chamber opening to establish a closed thermal boundary condition independent of external enclosure orientation. The sealing configuration is maintained under axial, radial, and torsional loading conditions encountered during transport, handling, and vibration events, thereby preserving payload isolation and thermal stability regardless of device orientation or motion.

In some embodiments, the sealing elements comprise elastomeric materials selected based on compression set resistance, low-temperature elasticity, and chemical compatibility with pharmaceutical and biological payloads. The sealing interfaces are configured to maintain effective sealing performance across repeated open-close cycles, with gasket compression maintained within a predetermined elastic operating range to avoid permanent deformation or loss of sealing force.

The cartridge assembly further defines a thermally decoupled user interaction zone at the top cover, wherein the ABS top cover material and associated structural features provide a reduced thermal conductivity pathway between the payload chamber and external user contact surfaces. This configuration minimizes user-perceived temperature gradients while preserving thermal isolation of the payload chamber, enabling safe and comfortable handling during active cooling operation.

In some embodiments, the outer surface of the aluminum shell includes a patterned texture or mesh geometry configured to increase external convective heat transfer surface area while simultaneously providing tactile grip characteristics. The external surface pattern can comprise knurling, perforations, lattice structures, or embossed features formed during machining or post-processing, with feature dimensions selected to balance convective performance, manufacturability, and ergonomic handling.

The cartridge assembly is further configured to operate as a passive thermal buffer when removed from an active cooling environment. The combined thermal mass of the aluminum shell, HDPE insert, and internal payload volume provides a defined thermal time constant that slows temperature rise during ambient exposure. This passive buffering capability enables short-duration transport or handling outside of an active cooling enclosure without exceeding allowable payload temperature limits.

In some embodiments, the internal geometry of the HDPE insert includes localized thickness variations, ribs, or recesses configured to tailor thermal diffusion characteristics within the payload chamber. These internal geometric features can be selected based on thermal modeling to bias cooling toward specific regions of the payload volume, reduce stratification effects, or accelerate temperature recovery following lid-open events.

The cartridge assembly further supports integration of sensing elements embedded within or adjacent to the cartridge insert. Temperature sensors, humidity sensors, or chemical indicators can be positioned within the HDPE insert wall or at the interface between the insert and the aluminum shell to provide real-time monitoring of payload conditions. Sensor placement at these locations enables direct measurement of payload temperature as well as indirect assessment of thermal coupling effectiveness between the cartridge assembly and an external cooling system.

In some embodiments, the cartridge assembly includes machine-readable identification features integrated into the outer shell or the cartridge outer shell material ring. These identification features can comprise optical markings, color-coded bands, barcodes, QR codes, or RFID elements configured to identify payload type, temperature specification, chain-of-custody information, or calibration status. The identification features can be permanently integrated or removably attached depending on operational requirements.

The cartridge architecture further enables scalable manufacturing through material substitution and dimensional scaling while preserving core thermal management principles. The aluminum outer shell thickness, insert material selection, and surface treatment parameters can be adjusted to accommodate different payload capacities, target temperature ranges, or regulatory requirements without altering the fundamental multi-layer thermal control architecture disclosed herein.

In some embodiments, the cartridge assembly is configured to interface with multiple host cooling systems through standardized outer geometry and thermal interface regions. The cylindrical outer shell defines one or more designated thermal coupling zones configured to contact planar, curved, or annular cooling surfaces within different host enclosures, enabling interoperability across multiple product platforms using a common cartridge design.

The cartridge assembly further provides a modular failure isolation advantage, wherein thermal or mechanical degradation of a single cartridge does not compromise the functionality of the host cooling system or adjacent cartridges. Individual cartridge assemblies can be removed from service, replaced, or refurbished independently, thereby improving system reliability, maintainability, and lifecycle cost characteristics.

In some embodiments, the cartridge assembly is configured to accommodate phase-change or thermal buffering materials within the insert or annular regions between the insert and outer shell. These materials can be selected to absorb or release latent heat during temperature excursions, further stabilizing payload temperature during transient events such as power interruptions, transport delays, or ambient temperature fluctuations.

The disclosed palm-sized cylindrical cartridge architecture provides a thermally optimized, mechanically robust, and modular solution for portable temperature-controlled storage that departs from conventional monolithic container designs by distributing thermal management functions across engineered material layers, surface treatments, and geometric interfaces. The integration of surface-engineered aluminum, compliant polymer inserts, and serviceable sealing structures enables performance characteristics not achievable through single-material or single-wall constructions.

Accordingly, the cartridge-based palm cooling system described herein represents a distinct and non-obvious advancement in portable thermal management technology by combining controlled surface micro-texture engineering, hydrocarbon-coated conductive substrates, mechanically adaptive interference interfaces, and modular integration capability within a compact cylindrical form factor optimized for autonomous thermal regulation of temperature-sensitive payloads.

### CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. A thermal management cartridge assembly comprising:
an outer shell comprising an aluminum substrate having a multi-layer surface treatment including an aluminum oxide layer, a micro-textured surface morphology, and a tetradecane hydrocarbon conformal coating, wherein said multi-layer surface treatment increases effective surface area relative to nominal geometric surface area and reduces junction-to-case thermal resistance compared to anodized-only surface preparations;
a cartridge insert positioned within said outer shell, said cartridge insert comprising High Density Polyethylene having a specified molecular density range and thermal conductivity value, wherein said cartridge insert is engaged with an interior surface of said outer shell through press-fit interference engagement, and wherein said High Density Polyethylene exhibits a thermal expansion coefficient substantially higher than that of said aluminum substrate;
a top cover comprising Acrylonitrile Butadiene Styrene thermoplastic polymer, said top cover configured to engage with said cartridge insert and said outer shell to provide environmental sealing; and
wherein said outer shell, said cartridge insert, and said top cover are arranged in coaxial alignment along a central longitudinal axis to form a cylindrical cartridge assembly configured for single-handed manual operation and portable transport.

2. The thermal management cartridge assembly of claim 1, wherein said cylindrical cartridge assembly has a height of approximately 7 inches and a diameter of approximately 3 inches.

3. The thermal management cartridge assembly of claim 1, wherein said aluminum substrate has been subjected to electrochemical anodization to form said aluminum oxide layer, abrasive sandblasting to create said micro-textured surface morphology characterized by controlled surface roughness values, and deposition of said tetradecane hydrocarbon conformal coating.

4. The thermal management cartridge assembly of claim 3, wherein said micro-textured surface morphology is characterized by surface roughness values in the range of 1.6 to 6.3 micrometers Ra.

5. The thermal management cartridge assembly of claim 1, wherein said micro-textured surface morphology increases effective surface area by a factor of 1.5 to 3.0 relative to nominal geometric surface area.

6. The thermal management cartridge assembly of claim 1, wherein said tetradecane hydrocarbon conformal coating has a thickness in the range of 2 to 10 micrometers.

7. The thermal management cartridge assembly of claim 1, wherein said multi-layer surface treatment reduces junction-to-case thermal resistance by 15-30% compared to anodized-only surface preparations.

8. The thermal management cartridge assembly of claim 1, wherein said High Density Polyethylene has a molecular density in the range of 0.93-0.97 g/cm³.

9. The thermal management cartridge assembly of claim 1, wherein said High Density Polyethylene exhibits thermal conductivity in the range of 0.42-0.51 W/m·K.

10. The thermal management cartridge assembly of claim 1, wherein said press-fit interference engagement has interference values of 0.05-0.15 millimeters.

11. The thermal management cartridge assembly of claim 1, wherein said High Density Polyethylene exhibits a thermal expansion coefficient of 100-200×10⁻⁶ K⁻¹.

12. The thermal management cartridge assembly of claim 1, wherein said aluminum substrate exhibits thermal conductivity of approximately 205 W/m·K.

13. The thermal management cartridge assembly of claim 1, wherein said aluminum oxide layer has a thickness in the range of 5-25 micrometers.

14. The thermal management cartridge assembly of claim 1, wherein said cylindrical cartridge assembly is configured for functional integration within a portable temperature-controlled enclosure, said cylindrical cartridge assembly functioning as a removable payload chamber that interfaces with a thermoelectric cooling system of said portable temperature-controlled enclosure through direct thermal coupling between said multi-layer surface treatment of said outer shell and an interior surface of an aluminum payload chamber of said portable temperature-controlled enclosure.

15. The thermal management cartridge assembly of claim 14, wherein said thermoelectric cooling system comprises a semiconductor chip mounted at an angular orientation relative to said aluminum payload chamber and a closed-loop cooling system thermally coupled to said semiconductor chip.
